(19) United States
(12) Patent Application Publication
(10) Pub. No.: US 2021/0351214 A1
(43) Pub. Date: Nov. 11, 2021

(54) IMAGE SENSOR AND SIGNAL PROCESSING METHOD THEREOF

(71) Applicant: EXPANTRUM OPTOELECTRONICS, Shanghai (CN)

(72) Inventor: Zhongshou HUANG, SHANGHAI (CN)

(73) Assignee: EXPANTRUM OPTOELECTRONICS, SHANGHAI (CN)

(21) Appl. No.: 16/931,720

(22) Filed: Jul. 17, 2020

(30) Foreign Application Priority Data
May 11, 2020 (CN) 202010393039.X

(51) Int. Cl. H01L 27/146

(52) U.S. Cl. CPC H01L 27/14621; H01L 27/14685

(57) ABSTRACT

An image sensor comprising a unique color filtration layer and a light conversion layer is described. The color filtration layer includes an array of color filtration regions, that at least one of the color filtration regions contains a color filter occupying 20% to 80% area of the color filtration region. The image sensor increases light sensitivity in low light condition while maintains enough chromatic information in image details.

### CROSS-REFERENCE TO RELATED APPLICATIONS

This application is based upon and claims the benefit of priority of Chinese Patent Applications No. 202010393039.X, filed on May 11, 2020, the entire contents thereof are incorporated herein by reference.

### TECHNICAL FIELD

The present disclosure relates to the field of photoelectric technology, specifically to an image sensor and a signal processing method.

### BACKGROUND

Image sensors are widely used in various digital image devices to capture optical images and create electronic images in digital format FIG. 1 is a plane view of an image sensor in the prior art, as an array of pixels. FIG. 2 is a cross-sectional view of the pixel. Each pixel 1 includes three sub-pixels, named red, green and blue sub-pixel, equipped with a red filter 11, a green filter 12 and a blue filter 13, respectively. A white light beam, which is in a broad spectrum, will become narrow band or color light beam after the filters. As shown in FIG. 2, a conversion layer 30 is positioned under the color filters, which comprises three conversion elements 31, 32 and 33, corresponding to the red, green and blue filters, respectively. Incident light beam, will be converted into three electronic signals, representing red, green and blue components in a chromatic image, respectively. Each sub-pixel further includes a switching transistor and perhaps other electronic components, for example a reset transistor and an amplifying transistor typically seen in a CMOS imaging sensor (not shown in FIG. 2). Black matrix 14 is arranged between filters of different colors to reduce detrimental crosstalk effects between different colors, and also to block stray lights reflecting or scattering from metal wires underneath the black matrix. Those metal wires include signal output line and various control lines to address the conversion layer.

FIG. 3 schematically illustrates four power spectrums, wherein L1 is a typical power spectrum of white light before a conventional RGB color layer, L2, L3, and L4 represent power spectrums of light after the white light passing through the blue filter, the green filter, and the red filter, respectively. As shown in FIG. 3, each color filter has a relatively high transmission rate in a certain color band but absorbed substantially all light in other color bands. For the sake of simplicity, it is assumed that more than two-thirds of the light photons are blocked by the RGB color filters. Therefore, in a low light environment without auxiliary lighting, the light photons reaching to each pixel are extremely limited, resulting significantly low signal to noise ratio in a color image acquisition.

Over the years, several techniques have been developed, aiming to improvement of color image quality in low light environment. For instance, RGW sub-pixel format, in which each pixel comprises three sub-pixels, red pixel, green pixel and white pixel, can increase the light sensitivity due to lack of color filter in the white pixel. In another example, RGBW sub-pixel format, in which a white sub-pixel is added into the conventional RGB sub-pixel combination to gain extra light sensitivity. However, adoption of a white sub-pixel in each pixel dots will inevitably reduce the chromaticity of a color image, resulting in yellowish or color wash-out in the worst case.

In contrast to the above sub-pixel rendering approaches, a pixel array formed mainly by white pixel dots has some color pixel dots scattering sparsely across the pixel array, named sparse color array, has been developed. The sparse color array provides significant improvement in low light sensitivity, because that more than half of the sub-pixels are white sub-pixels, which are transparent in all color band. The downside of utilizing the sparse color imaging sensor to capture color image in real scene, is that small color objects might be seriously distorted due to sub-sampling or even completely missing due to lack of color sampling dots. One easy understanding example is traffic light, missing chromatic details of the traffic light, is equivalent to missing or misinterpreting the sign, and may lead to terrible traffic accidents. Although increasing the number of color sub-pixels can mitigate the risk of losing chromatic details, the light sensitivity will be compromised due to the light attenuation in the color filters.

It is therefore difficult, in those approaches mentioned above, to realize an increased light sensitivity without compromising too much chromatic details at the same time.

### SUMMARY

An image sensor with the following configurations is disclosed in an embodiment, that the image sensor comprises: a conversion layer including an array of conversion elements to convert visible light into electronic signals; a filtration layer on the conversion layer including an array of filtration regions, that at least one of the filtration regions has a color filter occupying 20% to 80% area of the filtration region.

A signal processing method associated with the image sensor is disclosed in another embodiment, that the signal processing method comprises at least three main steps in order to retrieve an actual intensity spectrum of incident light: 1) receiving the electronic signals from the conversion layer; 2) retrieving the original intensity spectrum of incident light, based on pre-measured transmission spectrum of each filtration region; 3) sending a chromatic image signal, based on the retrieved intensity spectrum of the incident light, to a display device.

### BRIEF DESCRIPTION OF THE DRAWINGS

Embodiments of the present disclosure will be described, by way of example only, with reference to the accompanying schematic drawings in which corresponding reference symbols indicate corresponding parts, and in which:

FIG. 1 is a plane view of an image sensor in the prior art;

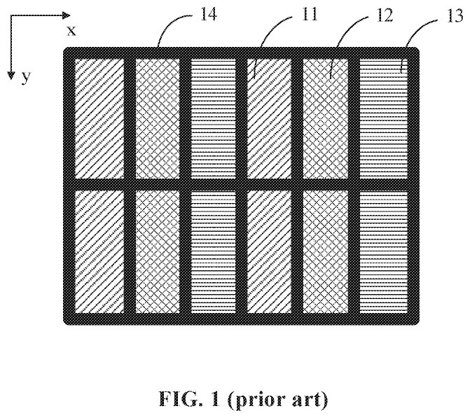

FIG. 2 is a cross-sectional view of the image sensor in the prior art;

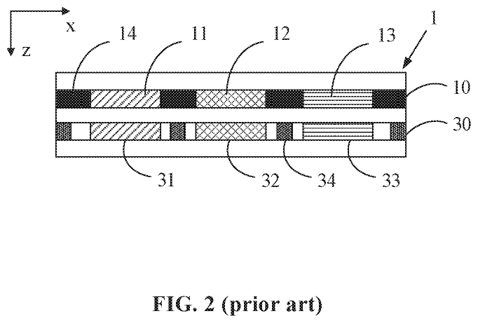

FIG. 3 shows four power spectrum plots for a natural daylight and the remaining light beams after the natural daylight passing through Red, Green, and Blue filtration, respectively:

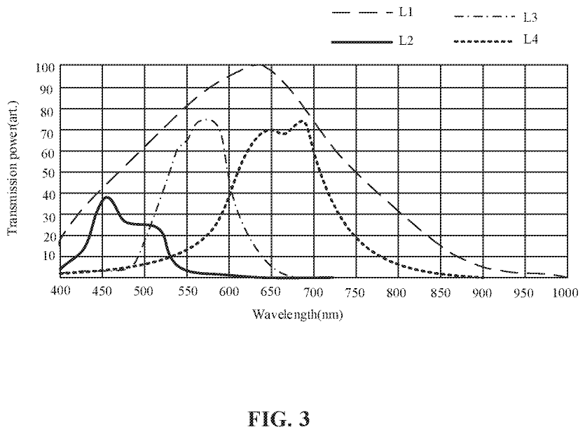

FIG. 4 is a schematic view of a filtration region according to a first embodiment of the present disclosure:

FIG. 5 is a plane view of a filtration layer of an image sensor according to the first embodiment of the present disclosure:

FIG. 6 is a cross-sectional view of the image sensor according to the first embodiment of the present disclosure:

FIG. 7 is a plane view of a filtration layer of an image sensor according to a second embodiment of the present disclosure:

FIG. 8 is a cross-sectional view of the image sensor according to the second embodiment of the present disclosure:

FIG. 9 is a plane view of a filtration layer of an image sensor according to a third embodiment of the present disclosure:

FIG. 10 is a cross-sectional view of the image sensor according to the third embodiment of the present disclosure:

FIG. 11 is a plane view of a filtration layer of an image sensor according to a fourth embodiment of the present disclosure:

FIG. 12 is a cross-sectional view of the image sensor according to the fourth embodiment of the present disclosure;

FIG. 13 is a plane view of a filtration layer of an image sensor according to a fifth embodiment of the present disclosure;

FIG. 14 is a cross-sectional view of the image sensor according to the fifth embodiment of the present disclosure;

FIG. 15 is a plane view of a filtration layer of an image sensor according to a sixth embodiment of the present disclosure;

FIG. 16 is a plane view of a filtration layer of an image sensor according to a seventh embodiment of the present disclosure;

FIG. 17 is a flow chart illustrating a signal processing method for the image sensor according to one embodiment of the present disclosure:

FIG. 18 schematically illustrates, with computer simulation results, how an area ratio between a color filter and a filtration region containing the color filter affects the signal to noise ratio.

### DETAILED DESCRIPTION

In the following, the technical contents of the present disclosure will be described with reference to the figures and embodiments. Same reference signs in the figures refer to same or similar structures, so repeated description of them will be omitted. The concept and its realizations of the present disclosure can be implemented in a plurality of forms, and should not be understood to be limited to the embodiments described hereafter. In contrary, these embodiments are provided to make the present disclosure more comprehensive and understandable, and so the conception of the embodiments can be conveyed to the technicians in the art fully.

The features, structures or characteristics described can be combined in any appropriate way in one or more embodiments. In the description below, many specific details are provided to explain the embodiments of the present disclosure fully. However, the technicians in the art should realize that, without one or more of the specific details, or adopting other methods, components, materials etc., the technical proposal of the present disclosure can still be realized. In certain conditions, structures, materials, or operations well known are not shown or described in detail so as not to obfuscate the present disclosure.

In one embodiment of the present disclosure, an image sensor is provided, that includes a filtration layer that allows light in certain spectral bands to pass through it, and a conversion layer to convert visible light into electronic signals. The filtration layer is overlapped on the conversion layer and on the light incident side. The filtration layer includes an array of filtration regions and perhaps other regions surrounding the array of the filtration regions, that at least one of the filtration regions is configured to have a color filter which occupies 20% to 80% area of the filtration region. For example, assume a green filter occupies 50% area of the filtration region, that allows only green light ranging from 490 nm to 580 nm in wavelength to pass through, which also suggests that another 50% space of the filtration region will let white light to pass through. In contrast to a conventional filter layout where a color filter is essentially continuously overlapping entire filtration region, the filter layout disclosed above is more like an isolated filter island or filter dot, and is named Dotted Filter and then related RGB Color Filter Array is named D-RGB CFA as acronym.

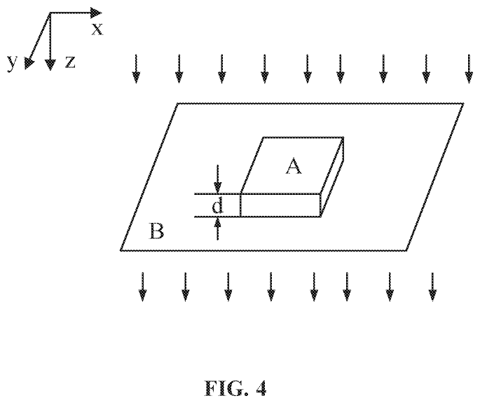

FIGS. 4-6 schematically illustrate an image sensor with the Dotted Filter layout according to a first embodiment, wherein the filtration region includes a Dotted Filter which occupies 20%-80% area of the filtration region. Refer to FIG. 4, in a X-Y-Z coordination system, the z-axis is in the direction of incident light, X-Y plane is in parallel with the filtration layer. Letter B refers to the area of the entire filtration region, letter A refers to the area of the filter, d refers to the thickness of the filter. To establish relationships between the filter layout and light output, assume φᵢₙ is an input light flux on the entire filter region, φₐ is a light flux after the filter, φ_{b} is a light flux after the rest area of the filtration region without filter, φₒᵤₜ is the total light flux after the filtration region, then these parameters are related each other in the following equation-sets (1)-(3):

$$\begin{matrix}{φ}_{b} = ( 1 - \frac{A}{B} ) \cdot {φ}_{in} & ( 1 ) \\ {φ}_{a} = \frac{A}{B} \cdot {φ}_{in} \cdot exp ( - α d ) & ( 2 ) \\ {φ}_{out} = {φ}_{a} + {φ}_{b} = {φ}_{in} [ \frac{A}{B} \cdot exp ( - α d ) + ( 1 - \frac{A}{B} ) ] & ( 3 )\end{matrix}$$

Wherein, α refers to absorption coefficient of the color filter, which is generally a function of wavelength.

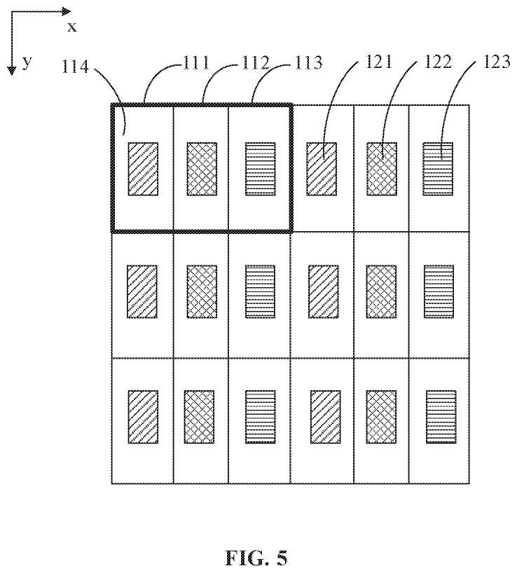

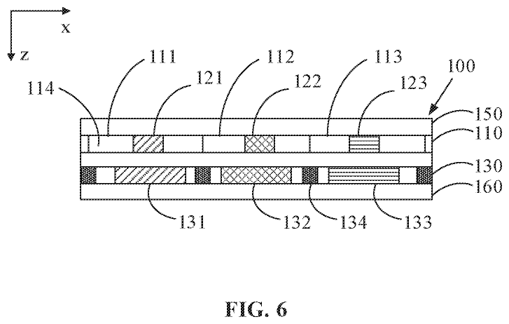

As shown in FIG. 5 and FIG. 6, a pixel 100 of the image sensor includes a transparent protection layer 150, a filtration layer 110, a conversion layer 130 and a substrate 160, overlapping one to another in sequence and along the direction of the incident light (the direction of the z-axis as well). The protection layer 150 can be a transparent substrate made of glass or other coating made of organic materials. The substrate 160 can be made of glass, or ceramics, or silicon or other materials. In the embodiment, the pixel 100 includes a red sub-pixel 121, a green sub-pixel 122, and a blue sub-pixel 123. The filtration layer in each pixel includes three filtration regions, 111, 112 and 113, corresponding to the three sub-pixels, respectively. Each of the three filtration regions further contains a Dotted Filter inside, in the color band corresponding to the sub-pixel type, i.e. a red filter 121, or a green filter 122, or a blue filter 123, respectively. FIG. 5 also schematically illustrates “empty” space 114 surrounding each of the Dotted Filter. Following the similar configuration, the conversion layer 130 includes three conversion elements 131, 132, 133, that respectively convert the light passing through the three filtration regions to electronic signals. The conversion element can be a photodiode made of various semiconductor materials, selecting from a group including hydrogenated amorphous silicon and crystalline silicon as widely employed in a CCD (Charger Coupled Device) or a CMOS (Complementary Metal Oxide Semiconductor) image sensors. The conversion layer 130 further includes metal wires 134, that includes signal lines and control lines to drive the conversion elements.

In the embodiment, the area ratio of the color filter and the entire filtration region can be made from 20% to 80% for various applications. The reasons behind this percentage range will be explained based on computer simulations given later in this disclosure. It must be indicated that the above area ratios do not necessarily equivalent to an area ratio of the color filter to the sub-pixel, because of those opaque metal wires inside of the sub-pixel. An area ratio of the filtration region to the sub-pixel is usually called fill-factor, representing a percentage that how much incident light flux can be utilized by an imaging sensor plate.

In the first embodiment shown in FIG. 5, the color filters 121, 122, 123 are all in rectangle shape that each side of the rectangles is in parallel to either x-axis or y-axis. Each color filter is located in the middle of the sub-pixel and surrounded by the area 114 which allows white light to pass through. The area of each color filter remains substantially equal in the first embodiment, however, as a variety of this embodiment, the color filters in different colors can have different areas, to accommodate chromaticity of ambient light, or some color requirements in imaging acquisition such as white balance. As another variety of this embodiment, the color filters 121, 122, 123 can be in other shapes, including circular disk or other non-rectangle shapes. As another variety of this embodiment, the color filters 121, 122, 123 can be located in non-central positions, leaning toward one side of the sub-pixel.

According to the layout of Dotted Color Filter shown in FIG. 4-6, electronic signal output from each sub-pixel actually is mixed with information of monochrome and white light. In other words, all signals from sub-pixels are not independent but correlated each other in terms of chromaticity information. Method and equation-set to retrieve the monochromic light information will be provided and discussed in detail later. Because of that, the transparent area 114 surrounding each color filters, becomes less concern in terms of color-related optical cross-talks, which phenomenon have been troubles for both imaging sensor makers and display panel makers. Benefitting from this color filter layout, a black matrix with much narrow width is applicable or even no black matrix is needed anymore, that further increases light sensitivity in low light conditions. The only thing left to be fixed is light reflection and scattering from the metal wires that would have been covered by color filter or black matrix as in a conventional imaging sensor layout. This issue can be readily solved by adding antireflection coating on all metal wires exposing to incident light directly.

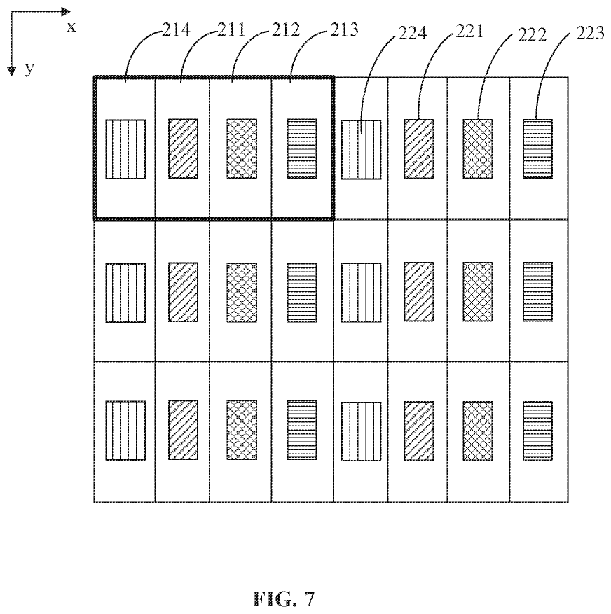

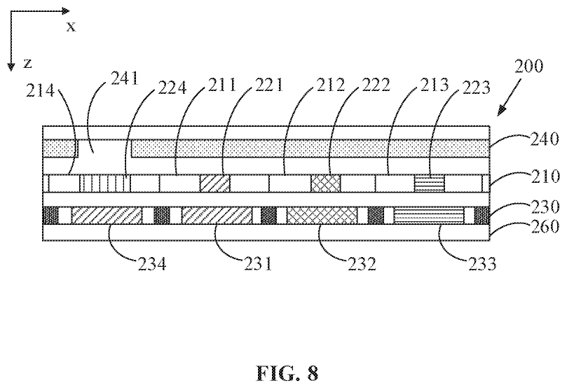

As shown in FIG. 7 and FIG. 8, in a second embodiment of the present disclosure, the image sensor includes an IR-cut filter 240, a filtration layer 210, a conversion layer 230, overlapped in sequence on a substrate 260. The IR-cut filter 240 is added to block infrared light, which is one add-on difference comparing with the first embodiment. Another main difference is that each pixel 200 now comprises four sub-pixels, especially including a sub-pixel for infrared light sensing with other three sub-pixels for R G B visible light sensing, respectively. An opening 241 is created on the IR-cut filter 240, to allow all incident light particularly including the IR to pass through. The opening 241 can be filled with a transparent film. Underneath the opening 241, an IR-band-pass filter 224 is inserted that allows only infrared light to pass through. The three visible light filtration regions 211, 212 and 213 contains a red filter 221, a green filter 222 and a blue filter 223, respectively. To accommodate RGB-IR, four color bands sensing, the conversion layer 230 includes four separate conversion elements 234, 231, 232, 233 to generate electronic signals corresponding to red, green, blue and infrared incident light flux. The image sensor can acquire a visible image and an infrared image at the same time with less color shifts causing by infrared light.

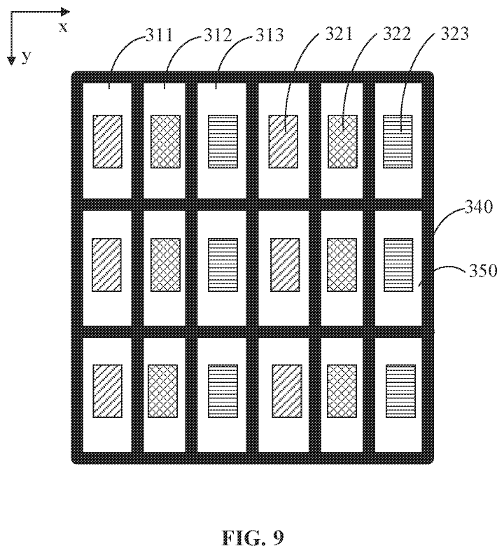

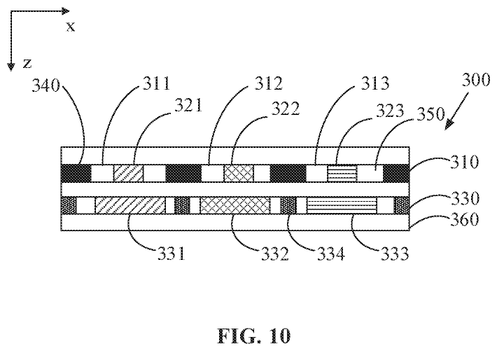

As shown in FIG. 9 and FIG. 10, in a third embodiment of the present disclosure, in addition to a filtration layer 310, a conversion layer 330, a substrate 360, and RGB color filters 321, 322 and 323, which are given and described in the previous embodiments, a black matrix 340 is placed between adjacent filtration regions and above the metal wires 334. Similar as stated in the previous embodiments, the color filter occupies 20% to 80% area of the filtration region. The black matrix 340 will prevent incident light from irradiating the metal wires and therefore reduce light reflections and scattering involved with the metal wires. The scheme of using a black matrix is applicable in the second embodiment as well.

In the embodiment, a transparent film 350 is added, in the empty space where are not covered by color filters and black matrix, aiming to planarizing the surface of the filtration layer. This planarization scheme is applicable in the second embodiment as well.

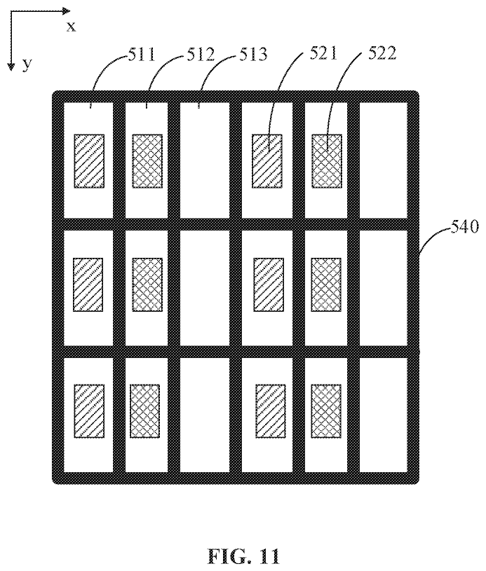

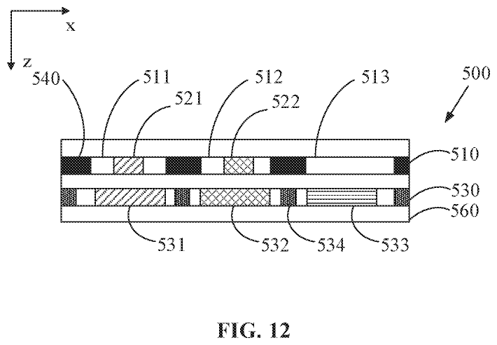

As shown in FIG. 11 and FIG. 12, in a fourth embodiment, an image sensor having RGW dotted color filters is schematically illustrated, wherein, each pixel comprises a red sub-pixel 511 with a red dotted filter 521, a green sub-pixel 512 with a green dotted filter 522, and a white sub-pixel 513 without any filter. Other elements marked with numbers can be recognized with their relative positions and by referring to the previous embodiments. Similar as described in the previous embodiments, the color filter occupies 20% to 80% area of the filtration region, and a black matrix 540 is positioned above the metal wires 534 to reduce light reflection and scattering. The black matrix can be omitted if the metal wires 534 is covered with an antireflection coating.

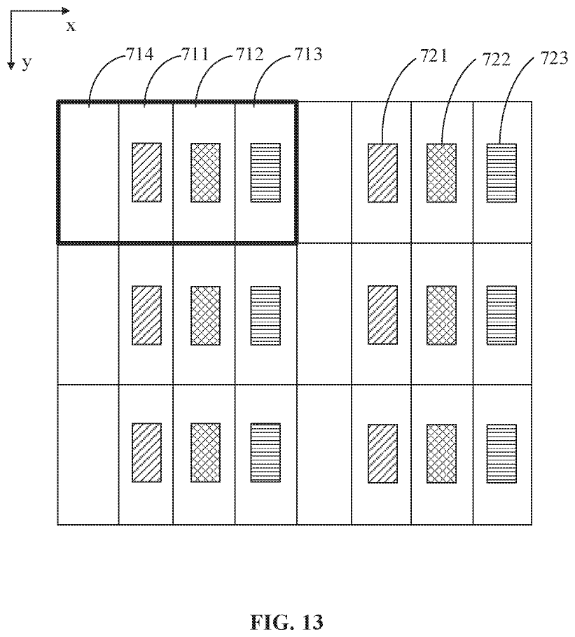

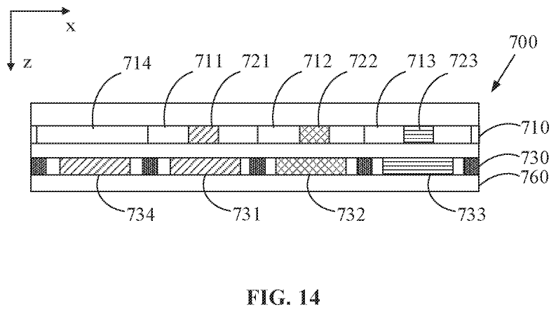

As shown in FIG. 13 and FIG. 14, in a fifth embodiment, another image sensor with dotted color filters is provided. The elements marked with numbers can be recognized with their relative positions and by referring to the previous embodiments. Similar as stated in the previous embodiments, the color filter occupies 20% to 80% area of the filtration region.

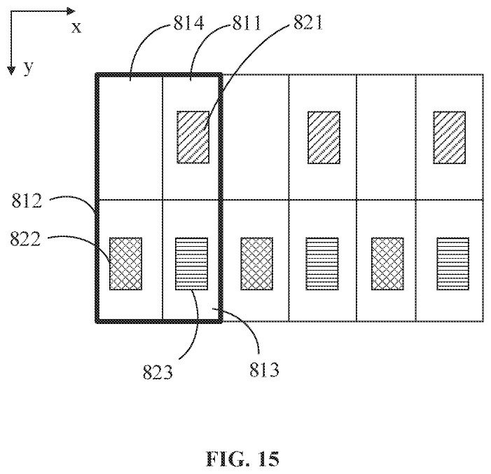

As shown in FIG. 15, in a sixth embodiment, an image sensor having RGBW dotted color filters is schematically illustrated, wherein, the four sub-pixels are arranged differently from the previous embodiment. Instead of aligning the four sub-pixels along one straight line, tiling them into a square shape will bring some advantages in device layout and efficiency of spatial sampling. Other elements marked with numbers can be recognized with their relative positions and by referring to the previous embodiments.

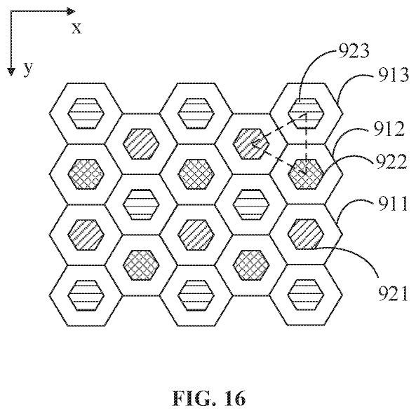

As shown in FIG. 16. In a seventh embodiment, an image sensor with RGB dotted color filters is schematically illustrated, wherein the three sub-pixels, are tiled in a honey-comb structure, and each sub-pixel is surrounded by other sub-pixels in different colors. Connecting the centers of three adjacent RGB sub-pixels with straight line will form a substantially equilateral triangle, therefore the tiling structure with the RGB sub-pixels in this embodiment can be named a Delta tilting. In the Delta tiling, space between adjacent dotted color filter are kept essentially equal, and therefore the light flux passing through the space are substantially equal.

Various tiling structure with the dotted color filter other than the rectangular tiling or the Delta tiling can be realized. The dotted color filters can be positioned in the center or leaning to one side of the filtration regions. It should be stated that, all feasible variations in layout, shapes and tiling structures with the dotted color filter in an imaging sensor are within the scope of the present invention.

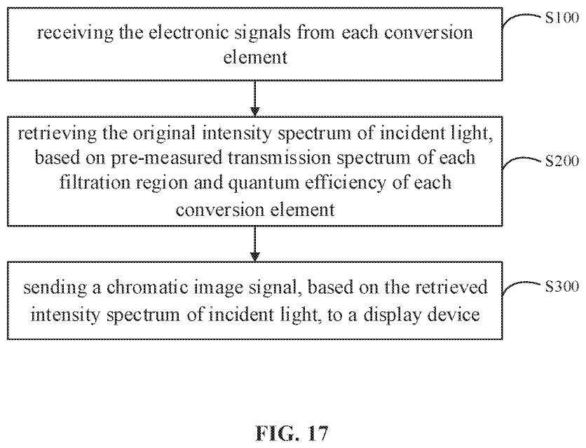

As mentioned previously in this disclosure, a signal processing method or an algorithm will be provided to retrieve the incident chromatic image signals. As shown in FIG. 17, an image sensor incorporated with this signal processing method will perform at least the following three processing steps:

S100, receiving the electronic signals from each conversion element;

S200, retrieving the original intensity spectrum of incident light, based on pre-measured transmission spectrum of each filtration region and quantum efficiency of each conversion element;

S300, sending a chromatic image signal, based on the retrieved intensity spectrum of incident light, to a display device.

The signal processing method is described in detail below by taking a pixel as an example. The pixel includes a plurality of sub-pixels, and assume the number of the sub-pixel is m. Each of the plurality of sub-pixels, contains its own filtration region, its own dotted color filter and its own light conversion element. It is fairly reasonable to assume that, when the dimension of a pixel is small enough compared to image details to be resolved, the light flux and its spectrum distribution in each sub-pixel are considered to be substantially equal. The incident light flux on a pixel φᵢₙ can be expressed by a sum of light flux on all sub-pixels (ignore the fill-factor for the sake of simplicity):

φᵢₙ=Σⱼ^{m}φⱼ (4)

wherein, φⱼ refers to the incident light flux of the j-th sub-pixel and jϵm. For RGB sub-pixel layout, m=3, for RGB-IR sub-pixel layout, m=4.

Now consider a pixel containing dotted color filter in each of its sub-pixel, which is the filter layout in several embodiments described above, the electronic signals read out from each conversion element can be expressed by the following equation-sets (5) and (6):

Sⱼ=Kⱼ·Iⱼ·φⱼ+(1−Kⱼ)−S_{w} (5)

S_{w}=Σⱼ^{m}ηⱼφⱼ (6)

wherein, Sⱼ refers to the electronic signal output from the conversion element covered by j-th color filter, Kⱼ refers to an area ratio between the j-th color filter and the j-th filtration region, ηⱼ refers to a quantum efficiency of the conversion element in color band j. Iⱼ refers to a product of ηⱼ and transmittance of the j-th color filter, S_{w} refers to the electronic signal output from a hypothetical “white” conversion element overlapped by a filtration region without color filter. Introducing the parameter of S_{w} in above equations is only for the sake of simplicity of math expression and calculation.

In the equation-sets (5) and (6), device dimension related parameters such as Kⱼ, and device characteristics related parameters such as Iⱼ and ηⱼ can be pre-measured, and then the incident light flux of each color component φⱼ can be solved after acquiring signal output.

Now consider a RGBW pixel with dotted color filters in three color sub-pixels, one of such examples is described in the fifth embodiment. Electronic signals from the four sub-pixels can be expressed by the following equation sets (6) to (9):

Sᵣ=K_{f}·Rᵣ·φᵣ+(1−K_{f})−S_{w} (6)

S_{g}=K_{f}·R_{g}·φ_{g}+(1−K_{f})·S_{w} (7)

S_{b}=K_{f}·R_{b}·φ_{b}+(1−K_{f})·S_{w} (8)

S_{w}=ηᵣ·φᵣ+η_{g}·φ_{g}+η_{b}·φ_{b} (9)

wherein, Rᵣ refers to a product of transmittance of the red filter and quantum efficiency of the conversion element for red light, R_{g} refers to a product of transmittance of the green filter and quantum efficiency of the conversion element for green light, R_{b} refers to a product of transmittance of the blue filter and quantum efficiency of the conversion element for blue light. K_{f} refers to an area ratio between a dotted color filter and the filtration region containing the filter, which ranges from 20% to 80%. S_{w} refers to the electronic signal output from the white sub-pixel, which is a sum of products of light flux in a specific color band and corresponding quantum efficiency. The above equation sets (6) to (9) are hold based on an assumption that the color filters are thick enough to allow only the light in a specific color to pass through.

Ideally, if there is no noise arising during the image acquisition, the area of the dotted color filters can be very small without hindering retrieving correct light spectrum. Unfortunately, various noise sources are inevitably added during the image acquisition and even during the signal processing. The noises are originated from some of the following sources but not limited to:

1) shot noises following Poisson distribution, the noise power is proportional to the photon number;

2) electronic noises generated by signal readout, such as KTC switching noise, the noise power is proportion to the switching capacitance in the sub-pixel;

3) digitization noises generated during A/D conversion;

4) noises generated after arithmetic operations of signals, for example, the shot noise power becomes (N+M) after subtracting a signal with M photons from another signal with N photons;

5) FPN (Fixed Pattern Noise) caused by variations in sensing performance of the sub-pixels;

6) FPN caused by measurement errors during pre-measurement of the transmission spectrum of the dotted color filter and other device parameters.

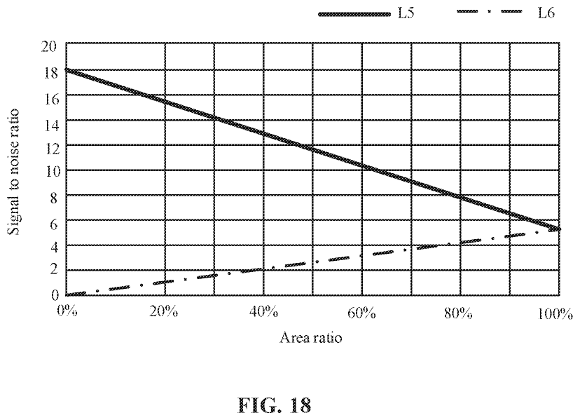

With various noise source present, signal to noise ratio will depend upon the area ratio of the dotted color filter to the filtration region. FIG. 18 schematically illustrates two curves of signal to noise ratio L5 and L6, based on computer simulation for a red sub-pixel. Assume the light flux into a sub-pixel is 2000 photons, and equivalent input electronic noise is 100 electrons. The curve L5 represents a “brightness” signal to noise ratio obtained from the sub-pixel, while the curve L6 represents a “color” signal to noise ratio, which is solved from the equation-set provided in the disclosure. Obviously, the brightness signal to noise ratio is inversely proportional to the area ratio, while the color signal to noise ratio is proportional to the area ratio. The two curves are merged at the last date point where the dotted color filter occupies 100% area of the filtration. It is indicated by the curve L6, to obtain a minimum and meaningful color signal to noise ratio, the area ratio is found to be approximately 20%.

Also indicated by the curve L5, the brightness signal to noise ratio is at 16 for 20% area ratio, it drops to 5 while the area ratio reaches 100%.

Once we acquired a black and white image in reasonably good brightness and contrast, objects in low light scene can be find out or recognized. In addition, we can paint the image containing the objects using the color signal, even it has signal to noise ratio merely larger than a unit. To fully utilize the power of this color painting technique after image acquisition, the area ratio of the Dotted Color Filter, found in the simulation results, is preferred to be in the range of 20% to 80%.

In summary, the present disclosure describes an image sensor incorporated with Dotted Color Filter. The image sensor and associated signal processing method, provide improved light sensitivity without losing color details, and therefore particularly useful for color image sensing in low light conditions.

The features, structures or characteristics described above can be combined in any appropriate way in one or more embodiments. The detailed descriptions of the embodiments of the present invention set forth the preferred modes contemplated by the inventor for carrying out the invention at the time of filing this application, and are not limitations. Accordingly, various modifications and variations obvious to a person with ordinary skill in the art to which it pertains are deemed to lie within the scope and spirit of the invention as set forth in the following claims.

What is claimed is:

1. An image sensor, comprising:
a conversion layer that comprises an array of conversion elements for converting visible light into electronic signals;
a filtration layer that overlaps on the conversion layer and comprises an array of filtration regions, wherein at least one filtration region comprises a color filter which occupies 20% to 80% area of the filtration region.

2. The image sensor according to claim 1, wherein the color filter is located in the middle of the filtration region.

3. The image sensor according to claim 1, wherein no black matrix is provided between adjacent filtration regions.

4. The image sensor according to claim 3, wherein metal wires located between adjacent conversion elements are covered with an antireflection coating.

5. The image sensor according to claim 1, wherein, a distance from the center of the color filter to the center of an adjacent color filter remains substantially equal.

6. The image sensor according to claim 5, wherein, the filtration regions are arranged in a honeycomb structure, and each filtration region is surrounded by filtration regions having color filters in different colors.

7. The image sensor according to claim 1, wherein, a transparent film is provided between adjacent color filters.

8. The image sensor according to claim 1, wherein at least one filtration region is transparent in white light without color filter.

9. The image sensor according to claim 1, also comprising a signal processing method, that performs at least the following three processing steps:
step 1, receiving the electronic signals from the conversion layer;
step 2, retrieving the original intensity spectrum of incident light, based on pre-measured transmissive spectrum of each filtration region;
step 3, sending a chromatic image signal, based on the retrieved intensity spectrum of the incident light, to a display device.

10. The signal processing method according to claim 9, wherein, the original intensity spectrum is retrieved based on the following equation-set:
$${S}_{j} = {K}_{j} \cdot {I}_{j} \cdot {φ}_{j} + ( 1 + {K}_{j} ) \cdot {S}_{w}$$
$${S}_{w} = {\sum }_{j}^{m} {η}_{j} {φ}_{j}$$
wherein, Sⱼ refers to the electronic signal output from the conversion element covered by j-th color filter, jϵm, m refers to the number of different color types, φⱼ refers to the incident light flux of the j-th sub-pixel, Kⱼ refers to an area ratio between an area of the j-th color filter and the j-th filtration region, ηⱼ refers to a quantum efficiency of the conversion element in color band j, Iⱼ refers to a product of ηⱼ and transmittance of the j-th color filter, S_{w} refers to the electronic signal output from a hypothetical conversion element without color filter overlapped.
